(19) United States
(12) Patent Application Publication
(10) Pub. No.: US 2020/0251452 A1
(43) Pub. Date: Aug. 6, 2020

(54) LED LIGHTING DEVICE, LED LAMP, AND LED DISPLAY SCREEN

(71) Applicants: Shanghai Sansi Electronic Engineering Co., Ltd., Shanghai (CN); Shanghai Sansi Technology Co., Ltd., Shanghai (CN); Jiashan Sansi Optoelectronic Technology Co., Ltd., Jiaxing (CN); Pujiang Sansi Optoelectronic Technology Co. Ltd., Jinhua City (CN)

(72) Inventors: Shan LI, Shanghai (CN); Ming CHEN, Shanghai (CN); Xiaoliang HE, Shanghai (CN); Shuyang FU, Shanghai (CN)

(73) Assignees: Shanghai Sansi Electronic Engineering Co., Ltd., Shanghai (CN); Shanghai Sansi Technology Co., Ltd., Shanghai (CN); Jiashan Sansi Optoelectronic Technology Co., Ltd., Jiaxing (CN); Pujiang Sansi Optoelectronic Technology Co. Ltd., Jinhua City (CN)

(21) Appl. No.: 16/853,758

(22) Filed: Apr. 21, 2020

(30) Foreign Application Priority Data
Jul. 1, 2019 (CN) 201921021063X
Jul. 1, 2019 (CN) 2019105856552

(51) Int. Cl. H01L 25/075; H01L 33/50; H01L 33/64

(52) U.S. Cl. CPC H01L 25/0753; H01L 33/507; H01L 33/641; H01L 33/505

(57) ABSTRACT

The present disclosure provides a LED lighting device, a LED lamp, and a LED display screen. The LED lighting device includes: a plurality of LED lighting units placed in a heat sink; the plurality of LED lighting units is packaged with at least one phosphor. That is, by using the LED lighting units to package the same phosphor or package a plurality of phosphors, the light color and even the color of the mixed light of the LED lighting units can be easily controlled, thus solving the problems of the traditional technology.

### CROSS REFERENCE TO RELATED APPLICATION

The present disclosure is related to and claims the benefit of priority to Chinese Patent Application No. 2019105856552, filed with SIPO on 1 Jul. 2019, and Chinese Patent Application No. 201921021063X, filed with SIPO on 1 Jul. 2019, the contents of which are incorporated herein by reference in their entirety.

### BACKGROUND

### Field of Disclosure

The present disclosure relates to the technical field of LED, in particular, to an LED lighting device, an LED lamp, and an LED display screen.

### Description of Related Arts

In the illumination of multi-LED lighting chips, how to perform light distribution to obtain the required light mixing is a technical problem in design.

### SUMMARY OF THE PRESENT DISCLOSURE

The present disclosure provides an LED lighting device, an LED lamp, and an LED display screen to solve the problems.

The LED lighting device includes: a plurality of LED lighting units placed in a heat sink; the plurality of LED lighting units is packaged with at least one phosphor.

In one or more embodiments of the present disclosure, the heat sink is made of a ceramic material.

In one or more embodiments of the present disclosure, light emitted by the plurality of LED lighting units is mixed into mixed light of a predetermined color to output.

In one or more embodiments of the present disclosure, the plurality of LED lighting units includes: one or more first lighting units; each of the first lighting units includes: a first LED lighting chip, and a first optical package component packaged outside the first LED lighting chip, wherein the first optical package component contains a first phosphor; wherein the first phosphor is stimulated by illumination of the first LED lighting chip, the color of a output light is mixed by a color of the first phosphor and a color of light emitted by the first LED lighting chip.

In one or more embodiments of the present disclosure, the plurality of LED lighting units further includes: one or more second lighting units; each of second first lighting units includes: a second LED lighting chip, and a second optical package component packaged outside the second LED lighting chip; wherein light emitted by the one or more second lighting units participates in the mixed light to set a color rendering index and/or a color temperature of the mixed light.

In one or more embodiments of the present disclosure, the LED lighting device comprises a plurality of first lighting units, colors of light emitted by the first LED lighting chips of the first lighting units are the same or different, and the first phosphors contain different compositions such that color temperatures of the light emitted by the first LED lighting chips are different.

In one or more embodiments of the present disclosure, the LED lighting device comprises a plurality of first lighting units, colors of light emitted by the first LED lighting chips of the first lighting units are the same, and the first phosphors contain same compositions such that color temperatures of the light emitted by the first LED lighting chips are the same.

In one or more embodiments of the present disclosure, the first phosphor includes: a phosphor having a plurality of primary colors matched with a color of light emitted by the first LED lighting chip to form white light.

In one or more embodiments of the present disclosure, each of the LED lighting units includes: at least two second lighting units, to respectively set a color rendering index and a color temperature of the mixed light.

In one or more embodiments of the present disclosure, the second optical package component includes a transparent phosphor or no phosphor.

In one or more embodiments of the present disclosure, the plurality of LED lighting units includes: a plurality of third lighting units; wherein colors of light emitted by the plurality of third lighting units cooperate with each other to be mixed into a mixed color of a predetermined color.

In one or more embodiments of the present disclosure, a color of light emitted by the plurality of third lighting units includes white, and a mutual matching type of the color includes: three primary colors, or three primary colors combined with one or more mixed colors.

In one or more embodiments of the present disclosure, each of the plurality of third lighting units includes: a third LED lighting chip, and a third optical package component packaged outside the third LED lighting chip, the third optical package component contains a third phosphor.

In one or more embodiments of the present disclosure, colors of light emitted by the plurality of third lighting chips are different, and the third phosphors in the third optical package components contain the same compositions.

In one or more embodiments of the present disclosure, colors of light emitted by the plurality of third lighting chips are the same, and the third phosphors in the third optical package components contain different compositions.

In one or more embodiments of the present disclosure, the third optical package components are connected with each other to form an integral package component having a smooth curved outer surface.

The present disclosure further provides an LED lamp, including: one or more of the LED lighting devices.

The present disclosure further provides an LED display screen, including: one or more of the LED lighting devices.

As described above, the present disclosure provides the LED lighting device, the LED lamp, and the LED display screen. The LED lighting device includes: a plurality of LED lighting units mounted on the heat sink; the plurality of LED lighting units is packaged with at least one phosphor. That is, by using the LED lighting units to package the same phosphor or package a plurality of phosphors, the light color and even the color of the mixed light of the LED lighting units can be easily controlled, thus solving the problems of the traditional technology.

### BRIEF DESCRIPTION OF THE DRAWINGS

FIG. 1 is a schematic diagram of an LED lighting device according to a first embodiment of the present disclosure.

FIG. 2 is a schematic diagram of the LED lighting device according to a second embodiment of the present disclosure.

FIG. 3 is a schematic diagram of the LED lighting device according to a third embodiment of the present disclosure.

FIG. 4 is a schematic diagram of the LED lighting device according to a fourth embodiment of the present disclosure.

### DETAILED DESCRIPTION OF THE PREFERRED EMBODIMENTS

The embodiments of the present disclosure will be described below. Those skilled can easily understand other advantages and effects of the present disclosure according to contents disclosed by the specification. The present disclosure can also be implemented or applied through other different specific embodiments. Various modifications or changes can also be made to all details in the specification based on different points of view and applications without departing from the spirit of the present disclosure. It needs to be stated that the embodiments and the features in the embodiments in the present disclosure can be combined with one another under the situation of no conflict.

The embodiments of the present disclosure are described in detail below with reference to the drawings, so that those skilled can easily implement the present disclosure. The present disclosure can be embodied in a variety of different forms and is not limited to the embodiments described herein.

In order to clarify the present disclosure, components that are not related to the description are omitted, and the same or similar components are denoted by the same reference numerals throughout the specification.

Throughout the specification, when a component is “connected” with another component, this includes not only the “direct connection” but also the “indirect connection” in which other elements are placed therebetween. In addition, when a certain component “includes” a certain element, unless otherwise stated, other elements are not excluded, other elements may be included.

When a component is referred to as being “above” another component, it may be directly above the other component, however, other components may also be accompanied between the two components. In contrast, when a component is referred to as being “directly above” another component, there are no other components between the two components.

Although the terms first, second, etc. are used herein to describe various elements in some embodiments, these elements should not be limited by these terms. These terms are only used to distinguish one element from another, such as the first interface and the second interface. In addition, as used herein, the singular forms “a”, “an” and “the” are intended to include the plural forms as well, unless the context clearly indicates otherwise. It should be further understood that the terms “comprise”, “include” indicate that there are the described features, steps, operations, elements, components, items, categories, and/or groups, but the existence, appearance, or addition of one or more other features, steps, operations, elements, components, items, categories, and/or groups are not excluded. The terms “or” and “and/or” are used herein to be interpreted as inclusive or meaning any one or any combination. Thus, “A, B or C” or “A, B and/or C” means “any one of the following: A; B; C; A and B; A and C; B and C; A, B and C”. An exception to this definition occurs only when a combination of elements, functions, steps or operations are inherently mutually exclusive in some manner.

The terminology used herein is only for the purpose of the description of special embodiments, and is not intended to limit the present disclosure. The singular form as used herein includes plural forms as long as the statement does not explicitly indicate the opposite. The word “include” used in the specification means the materialization of the specific features, regions, integers, steps, operations, elements and/or components, and does not exclude the existence or addition of other features, regions, integers, steps, operations, elements and/or components.

Terms referring to relative spaces such as “under”, “above”, etc. may be used to more easily illustrate the relationship of one component to another component illustrated in the drawings. Such terms refer to not only the meanings indicated in the drawings, but also other meanings or operations of the device in use. For example, a component that is described as “under” other components is described as “above” other components if the device in the drawings is turned over. Therefore, the term “under” is used to include all of the above and under. The device can be rotated by 90° or other angles, and terms representing relative space are also explained accordingly.

Although not defined differently, all terms including the technical terms and scientific terms used herein have the same meaning as commonly understood by those skilled in the technical field to which the present disclosure relates. The terms defined in the commonly used dictionary are additionally interpreted as having meanings consistent with the contents of the related technical documents and the current prompts, and as long as they are not defined, they should not be overly interpreted as ideal or very formulaic meanings.

The present disclosure provides one or more phosphors packaged in a plurality of LED lighting units, in combination with various original colors emitted by the LED lighting chips, to solve the traditional technical problems.

The present disclosure provides an LED lighting device, including: a plurality of LED lighting units placed in a heat sink; the plurality of LED lighting units is packaged with at least one phosphor.

In an exemplary embodiment, each LED lighting unit includes an LED lighting chip and an optical package component enclosing the LED lighting chip. The optical package component may be made of a lens material or may be an encapsulant. It is optional to provide phosphors of one or more colors in the optical package component, such as coating phosphors in the lens material, or making encapsulants with mixed phosphors.

It can be understood that the phosphor is stimulated by the light emitted by the LED lighting chip, and the color of the light emitted by the phosphor is complementary to the color of light emitted by the LED lighting chip. That is, the color of the light emitted after the phosphor is stimulated is the mixed color of the light emitted by the LED lighting chip and the phosphor.

For example, the light emitted by each of the LED lighting units may be, for example, white light, or may be a primary color light for mixing into white light, such as R (red), G (green), B (blue), etc., or other colors. Correspondingly, the type and color of the phosphor in each optical package component may be matched with the color of the LED lighting chip to be mixed into the white light or corresponding color light.

For example, an optical package component of the LED lighting unit contains three primary color phosphors, that is, red phosphor, green phosphor, and blue phosphor. The LED lighting chip may emit ultraviolet light using, for example, an ultraviolet LED chip to stimulate three primary colors of phosphor to form white light. Alternatively, the optical package component contains yellow phosphor, the LED lighting chip emits blue light, the blue light and the yellow light are mixed to form white light.

Alternatively, the three LED lighting units respectively emit red light, green light, and blue light, which may be mixed into white light to output. The color of the light emitted by the three LED lighting units may be obtained by stimulating the phosphor of the corresponding color with, for example, the light of the ultraviolet LED chip, or may be obtained by the LED chip emitting light of the corresponding color.

The structure of the exemplary LED lighting device is shown below by various embodiments.

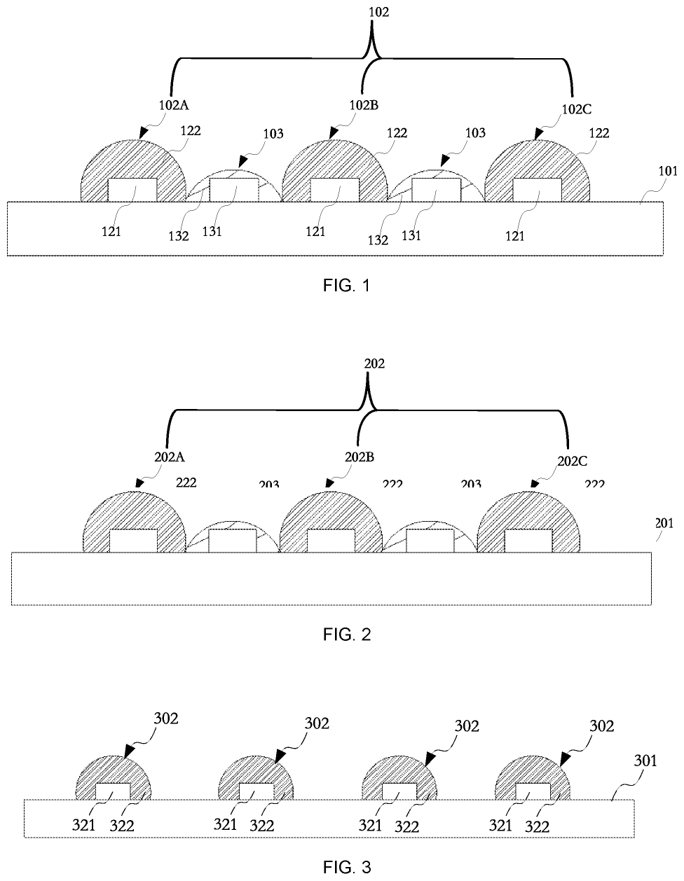

As shown in FIG. 1, a schematic diagram of an LED lighting device according to a first embodiment of the present disclosure is shown.

In the present embodiment, a plurality of LED lighting units is mounted on a heat sink 101.

The heat sink is preferably a ceramic heat sink. The plurality of LED lighting units corresponds to a plurality of LED lighting chips, and there is a large amount of heat. The ceramic material has high thermal conductivity. Therefore, a heat sink of the ceramic material can solve the heat dissipation problem.

The plurality of LED lighting units includes: a plurality of first lighting units 102. Although three are shown in the diagram of this embodiment, it is not limited thereto.

In this embodiment, each of the first lighting units 102 can emit light of a predetermined color (for example, white, or other colors such as red, orange, yellow, green, cyan, blue, purple, etc.). The color temperatures between the colored light emitted by different first lighting units 102 may be different. For example, the color temperatures of the white light emitted by the first lighting unit 102A, the first lighting unit 102B, and the first lighting unit 102C are different.

Specifically, in an exemplary embodiment, each of the first lighting units 102 includes: a first LED lighting chip 121, and a first optical package component 122 packaged outside the first LED lighting chip 121, the first optical package component 122 contains a first phosphor. The first phosphor is stimulated by illumination of the first LED lighting chip 121 to output colored light.

For example, when the first lighting unit 102 emits white light, the light colors of the first LED lighting chips 121 of the first lighting unit 102A, the first lighting unit 102B, and the first lighting unit 102C may be the same, for example, the light colors are all blue light or ultraviolet light, or may be different, for example, part is the blue light, and the other part is ultraviolet light. The first phosphors are different in composition. For example, the first phosphors are configured by at least three primary colors R, G, and B. The ratios or contents of the R, G, and B phosphors in one or more first phosphors may be different, or the first phosphors may be doped with phosphors of other colors than R, G, and B (for example, yellow Y and/or cyan G, etc.).

Optionally, the LED lighting device further includes: one or more second lighting units 103. This embodiment has two second lighting units 103, but the number is not limited thereto.

Light emitted by the one or more second lighting units 103 participates in the mixed light to set a color rendering index and/or a color temperature of the mixed light. Optionally, in this embodiment, the second lighting unit 103 is shown as two, that is, at least two. One of the second lighting units is used to set the color rendering index of the mixed light (the mixed light refers to the white light emitted by the first lighting unit 102A, the first lighting unit 1028, and the first lighting unit 102C), and the other is used to set the color temperature of the mixed light.

The setting refers to that due to the presence of the second lighting unit 103, the light emitted by the second lighting unit 103 participates in the light mixing, thereby changing the color temperature/color rendering index of the mixed light. In the case the light emitted from the second lighting unit 103 is determined, the color temperature/color rendering index of the mixed light can be controlled by adding the second lighting unit 103 to the LED lighting device.

Each of second first lighting units 103 includes: a second LED lighting chip 131, and a second optical package component 132 packaged outside the second LED lighting chip 131. Optionally, the second optical package component 132 contains a transparent phosphor or no phosphor, and the second LED lighting chip 131 may be selected to emit light with a desired color, such as blue. Of course, the second optical package component 132 may contain a phosphor of a desired color, and the color of the phosphor and the light color of the LED lighting chip can be found in the above embodiments or in the traditional colorimetry. Details will not be described herein.

FIG. 2 shows a schematic diagram of the LED lighting device according to a second embodiment of the present disclosure.

Compared with the first embodiment, the heat sink 201 is still used to dissipate heat from the plurality of LED lighting units 202. The main difference between this embodiment and the first embodiment is that: the first phosphors in the first optical package components 222 of the first lighting unit 202A, the first lighting unit 202B, and the first lighting unit 202C have the same composition. The first LED lighting chips 221 in the first optical package components 222 of the first lighting unit 202A, the first lighting unit 202B and the first lighting unit 202C may be the same, thereby outputting mixed light of a fixed color temperature; or may be different, such as different power, lighting colors, and the like.

The structure of the second lighting unit 203 in this embodiment may be similar to that of the second lighting unit 103 in the first embodiment, and thus will not be described again.

FIG. 3 is a schematic diagram of the LED lighting device according to a third embodiment of the present disclosure.

A plurality of LED lighting units is mounted on the heat sink 301. Compared with the foregoing first embodiment and second embodiment, the main differences of this embodiment are:

The plurality of LED lighting units includes: a plurality of third lighting units 302. Colors of light emitted by the plurality of third lighting units 302 cooperate with each other to be mixed into a desired mixed color.

In an exemplary embodiment, the mixed light as white light is taken as an example, a mutual matching type of the color of light emitted by the plurality of third lighting units 302 includes: three primary colors, or three primary colors combined with one or more mixed colors.

For example, in FIG. 3, four third lighting units 302 are shown, three of which emit light of R, G, B colors, so that they can be mixed into white light. The color of light emitted by the remaining one of the third lighting units 302 is a color for mixing light, such as yellow Y or cyan G.

Each of the plurality of third lighting units 302 includes: a third LED lighting chip 321, and a third optical package component 322 packaged outside the third LED lighting chip 321, the third optical package component 322 contains a third phosphor.

Optionally, in some embodiments, the third LED lighting chips 321 of the third lighting units 302 emit different light, while the third phosphors contain the same composition. For example, four third lighting LED chips respectively output light having R, G, B, and Y colors, and all of the third phosphors may be transparent. Alternatively, the four third LED lighting chips output ultraviolet light, while the third phosphors respectively correspond to the R, G, B, and Y colors.

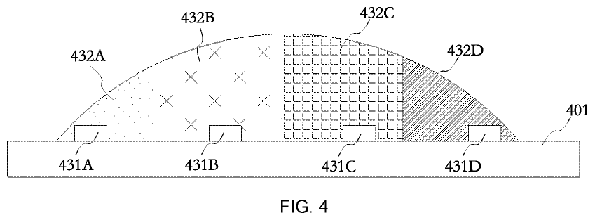

FIG. 4 shows a schematic diagram of the LED lighting device according to a fourth embodiment of the present disclosure.

The heat sink 401 is still used for heat dissipation. Compared with the foregoing third embodiment, the main differences of this embodiment are:

The colors of the third phosphors disposed in the third optical package components 432A, 432B, 432C, and 432D of the third lighting units may be different, and the colors of light emitted by the third LED lighting chips 431A, 431B, 431C, 431D may be the same.

In this embodiment, each of the third optical package components 432A, 432B, 432C, 432D (such as encapsulants) may be used as a part to form an integral package component having a smooth curved outer surface, that is, it looks like a curved lens in appearance, but is actually spliced by the third optical package components 432A, 432B, 432C, and 432D having different shapes as components.

The LED lighting device described in the above embodiments may be applied to an actual product, such as an LED lamp, an LED display screen, etc. The actual product may include one or more LED lighting devices in the above embodiments. The desired mixed light output can be achieved by selecting a plurality of LED lighting units that are packaged with the same or different types of phosphors. In addition, the good heat dissipation performance of the LED lighting device can be achieved by using the ceramic heat sink, to dissipate heat from the plurality of LED lighting units in the embodiment of the present disclosure, thus effectively improving the service life of the LED lamp and the LED display screen, and improving the user experience.

In summary, the present disclosure provides the LED lighting device, the LED lamp, and the LED display screen. The LED lighting device includes: a plurality of LED lighting units mounted on the heat sink; the plurality of LED lighting units is packaged with at least one phosphor. That is, by using the LED lighting units to package the same phosphor or package a plurality of phosphors, the light color and even the color of the mixed light of the LED lighting units can be easily controlled, thus solving the problems of the traditional technology.

The above-mentioned embodiments are just used for exemplarily describing the principle and effects of the present disclosure instead of limiting the present disclosure. Those skilled can make modifications or changes to the above-mentioned embodiments without going against the spirit and the range of the present disclosure. Therefore, all equivalent modifications or changes made by those who have common knowledge in the art without departing from the spirit and technical concept disclosed by the present disclosure shall be still covered by the claims of the present disclosure.

We claim:

1. An LED lighting device, comprising:
a plurality of LED lighting units mounted on a heat sink, the plurality of LED lighting units is packaged with at least one phosphor.

2. The LED lighting device according to claim 1, wherein the heat sink is made of a ceramic material.

3. The LED lighting device according to claim 1, wherein light emitted by the plurality of LED lighting units is mixed into mixed light of a predetermined color to output.

4. The LED lighting device according to claim 1, wherein
the plurality of LED lighting units comprises: one or more first lighting units;
each of the first lighting units includes:
a first LED lighting chip, and
a first optical package component packaged outside the first LED lighting chip, the first optical package component contains a first phosphor, wherein
the first phosphor is stimulated by illumination of the first LED lighting chip, a color of a output light is mixed by a color of the first phosphor and a color of light emitted by the first LED lighting chip.

5. The LED lighting device according to claim 4, wherein
the plurality of LED lighting units further comprises: one or more second lighting units;
each of second first lighting units includes:
a second LED lighting chip, and
a second optical package component packaged outside the second LED lighting chip; wherein
light emitted by the one or more second lighting units participates in the mixed light to set a color rendering index and/or a color temperature of the mixed light.

6. The LED lighting device according to claim 4, wherein
the LED lighting device comprises a plurality of first lighting units,
colors of light emitted by the first LED lighting chips of the first lighting units are the same or different, and
the first phosphors contain different compositions, such that color temperatures of the light emitted by the first LED lighting chips are different.

7. The LED lighting device according to claim 4, wherein
the LED lighting device comprises a plurality of first lighting units,
colors of light emitted by the first LED lighting chips of the first lighting units are the same, and
the first phosphors contain same compositions, such that color temperatures of the light emitted by the first LED lighting chips are the same.

8. The LED lighting device according to claim 4, wherein the first phosphor comprises: a phosphor having a plurality of primary colors matched with a color of light emitted by the first LED lighting chip to form white light.

9. The LED lighting device according to claim 5, wherein each of the LED lighting units comprises: at least two second lighting units, to respectively set a color rendering index and a color temperature of the mixed light.

10. The LED lighting device according to claim 4, wherein the second optical package component comprises a transparent phosphor or no phosphor.

11. The LED lighting device according to claim 1, wherein the plurality of LED lighting units comprises:
a plurality of third lighting units; wherein colors of light emitted by the plurality of third lighting units cooperate with each other to be mixed into a mixed color of a predetermined color.

12. The LED lighting device according to claim 11, wherein
a color of light emitted by the plurality of third lighting units includes white, and
a mutual matching type of the color comprises: three primary colors, or three primary colors combined with one or more mixed colors.

13. The LED lighting device according to claim 11, wherein each of the plurality of third lighting units comprises:
a third LED lighting chip, and
a third optical package component packaged outside the third LED lighting chip, the third optical package component contains a third phosphor.

14. The LED lighting device according to claim 13, wherein
colors of light emitted by the plurality of third lighting chips are different, and
the third phosphors in the third optical package components contain same compositions.

15. The LED lighting device according to claim 13, wherein
colors of light emitted by the plurality of third lighting chips are the same, and
the third phosphors in the third optical package components contain different compositions.

16. The LED lighting device according to claim 13, wherein the third optical package components are connected with each other to form an integral package component having a smooth curved outer surface.

17. The LED lighting device according to claim 14, wherein the third optical package components are connected with each other to form an integral package component having a smooth curved outer surface.

18. The LED lighting device according to claim 15, wherein the third optical package components are connected with each other to form an integral package component having a smooth curved outer surface.

19. An LED lamp, comprising: one or more LED lighting devices, the LED lighting device comprises:
a plurality of LED lighting units mounted on a heat sink, the plurality of LED lighting units is packaged with at least one phosphor.

20. An LED display screen, comprising: one or more LED lighting devices, the LED lighting device comprises:
a plurality of LED lighting units mounted on a heat sink, the plurality of LED lighting units is packaged with at least one phosphor.
